(19) United States
(12) Patent Application Publication
(10) Pub. No.: US 2005/0225463 A1
(43) Pub. Date: Oct. 13, 2005

(54) High-speed MASH sigma-delta modulator architecture and method of operation thereof

(75) Inventors: Sameh S. Rezeq, Dallas, TX (US); Robert B. Staszewki, Garland, TX (US); Kurram Muhammad, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/821,487

(22) Filed: Apr. 9, 2004

(51) Int. Cl. H03M 3/00

(52) U.S. Cl. 341/143

(57) ABSTRACT

A sigma-delta modulator, a method of performing sigma-delta modulation and an digital-to-analog converter incorporating the modulator or the method. In one embodiment, the sigma-delta modulator includes: (1) a lower-order accumulator chain configured to process only lower-order bits of an input number, (2) a higher-order accumulator chain configured to process only higher-order bits of the input number and (3) a combiner coupled to both the lower-order and higher-order accumulator chains and configured to align results therefrom to generate output bits of a given order.

### TECHNICAL FIELD OF THE INVENTION

The present invention is directed, in general, to sigma-delta modulators and, more specifically, to a Multistage Noise Shaping (MASH) sigma-delta modulator architecture that is optimized for high speed operation and a method of performing sigma-delta modulation.

### BACKGROUND OF THE INVENTION

Sigma-delta modulators (also known as ΣΔ, delta-sigma or SE modulators) are closed loop modulators that provide high resolution, low cost data conversion. A multistage noise shaping (MASH) sigma-delta modulator is a type of sigma-delta modulator that provides more than one stage of bit processing. For example, a third order MASH (“MASH3”) sigma-delta modulator provides three stages of noise shaping for a digital input number. Accordingly, MASH sigma-delta modulators are employed in digital-to-analog converters throughout the industry. In the area of communications, for example, digital-to-analog converters employing MASH sigma-delta modulators are commonly used in radio frequency (RF) transceivers.

Often, accumulators used in these MASH sigma-delta modulators are synthesized in integrated circuits. For processing a high number of bits (greater than five bits) for operating at RF frequencies, implementing the accumulators can be difficult. Thus, MASH sigma-delta modulators are not feasible for a high number of bits at RF frequencies. This is especially true for synthesizing the accumulators for a digital radio processor (DRP) using a deep-submicron digital complementary metal-oxide semiconductor (CMOS) process. A deep-submicron digital CMOS process involves feature dimensions on the order of less than about 0.25 μm.

Accordingly, what is needed in the art is a sigma-delta modulator capable of operating at a high speed. More specifically, a sigma-delta modulator is needed that can be synthesized in an integrated circuit and operate at a high speed.

### SUMMARY OF THE INVENTION

The present invention is founded on the broad recognition that narrower accumulators operate faster than wider accumulators and therefore that a sigma-delta modulator can be made faster by splitting the accumulators into multiple parallel chains of narrower accumulators and dividing the various bits of the input number between or among the chains. Any delays necessary to align the output bits are straightforward relative to schemes that require the entire sigma-delta modulator to be partitioned.

Thus, in one aspect, the present invention provides a sigma-delta modulator. In one embodiment, the sigma-delta modulator includes: (1) a lower-order accumulator chain configured to process only lower-order bits of an input number, (2) a higher-order accumulator chain configured to process only higher-order bits of the input number and (3) a combiner coupled to both the lower-order and higher-order accumulator chains and configured to align results therefrom to generate output bits of a given order.

In another aspect, the present invention provides a method of performing sigma-delta modulation. In one embodiment, the method includes: (1) processing only lower-order bits of an input number in a lower-order accumulator chain, (2) processing only higher-order bits of the input number in a higher-order accumulator chain and (3) aligning results from both the lower-order and higher-order accumulator chains to generate output bits of a given order.

As mentioned above, digital-to-analog conversion is one of many advantageous applications for sigma-delta modulation. Accordingly, in yet another aspect, the present invention provides a digital-to-analog converter. In one embodiment the digital-to-analog converter includes: (1) digital circuitry configured to provide input numbers from a digital input (2) a sigma-delta modulator coupled to the oversampling circuit and having: (2a) a lower-order accumulator chain that processes only lower-order bits of the input numbers, (2b) a higher-order accumulator chain that processes only higher-order bits of the input numbers and (2c) a combiner, coupled to both the lower-order and higher-order accumulator chains, that aligns results therefrom to generate output bits of a given order and (3) a digital-to-continuous converter, coupled to the sigma-delta modulator, that converts the output bits into a continuous domain.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

For a more complete understanding of the present invention, reference is now made to the following descriptions taken in conjunction with the accompanying drawings, in which:

FIG. 1 illustrates a schematic diagram of one embodiment of a MASH3 sigma-delta modulator constructed according to the principles of the present invention in which two accumulator chains are employed to process half of the input number bits apiece;

FIG. 2 illustrates a schematic diagram of one embodiment of a MASH3 sigma-delta modulator constructed according to the principles of the present invention in which three accumulator chains are employed to process a third of the input number bits apiece;

FIG. 3 illustrates a schematic diagram of one embodiment of a MASH3 sigma-delta modulator constructed according to the principles of the present invention in which four accumulator chains are employed to process a quarter of the input number bits apiece;

FIG. 4 illustrates a flow diagram of one embodiment of method of performing a sigma-delta modulation carried out according to the principles of the present invention; and

FIG. 5 illustrates a schematic diagram of one embodiment of an digital-to-analog converter incorporating a MASH3 sigma-delta modulator constructed according to the principles of the present invention.

### DETAILED DESCRIPTION

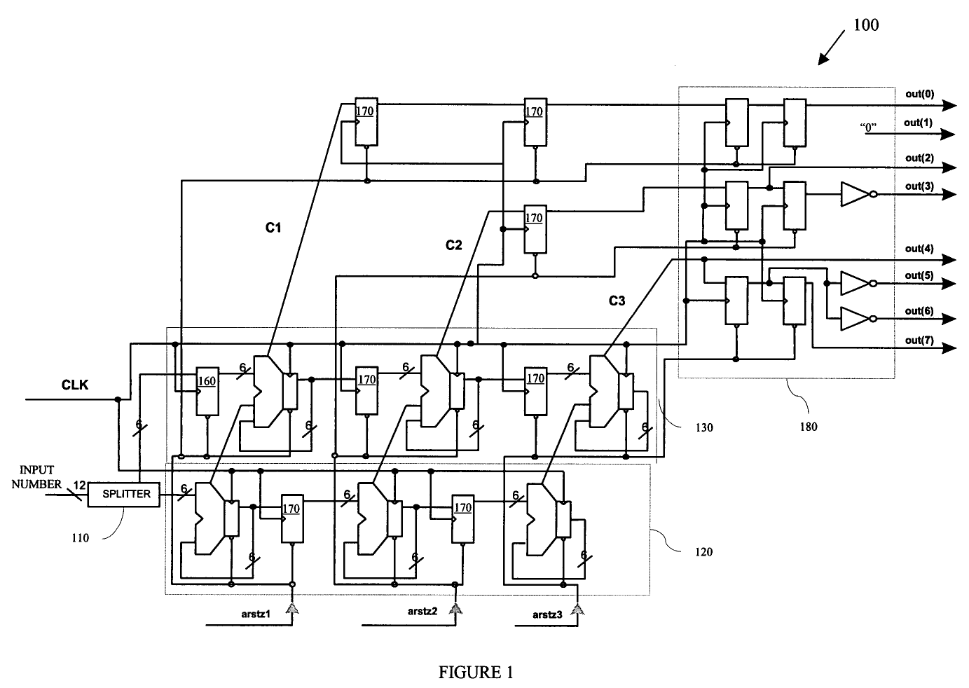

Referring initially to FIG. 1, illustrated is a schematic diagram of one embodiment of a MASH3 sigma-delta modulator, generally designated 100, constructed according to the principles of the present invention. The MASH3 sigma-delta modulator 100 includes a splitter 110, a lower-order accumulator chain 120, a higher-order accumulator chain 130, pre-accumulator delay logic 160, inter-accumulator delay logic 170 and a combiner 180.

The MASH3 sigma-delta modulator 100 is configured to receive 12 parallel bits of an input number. Typically, the input number is generated from data input of a digital-to-analog converter. The MASH3 sigma-delta modulator 100 operates like a conventional MASH3 sigma-delta modulator, except instead of processing the entire input number in a single accumulator chain, the MASH3 sigma-delta modulator 100 divides the input number and employs the lower-order accumulator chain 120 and higher-order accumulator chain 130 to process half of the 12 input number bits apiece.

The splitter 110 is a conventional splitter coupled to the lower-order accumulator chain 120 and the higher-order accumulator chain 130. The splitter 110 is configured to receive and then divide the 12 bit input number into six higher-order bits and six lower-order bits. Thus, the lower-order bits equal in number to the higher-order bits. Of course, in other embodiments, the number or high order bits may differ from the number of low-order bits. The six lower-order bits are sent to the lower-order accumulator chain 120 and the six higher-order bits are sent to the higher-order accumulator chain 130.

The lower-order accumulator chain 120 employs three six bit accumulators coupled together in series to process the six lower-order bits of the input number. The higher-order accumulator chain 130 also employs three six bit accumulators coupled together in series to process the six higher-order bits of the input number. The MASH3 sigma-delta modulator 100 therefore has an equal number of accumulators in the lower-order accumulator chain 120 and the higher-order accumulator chain 130. The number of accumulators in each accumulator chain 120, 130 is equal to the given order of the MASH3 sigma-delta modulator 100: three. Thus, the lower-order accumulator chain 120 and the higher-order accumulator chain 130 provide three stages of bit processing for the lower-order bits and the higher-order bits, respectively. In one embodiment, the lower-order accumulator chain 120 and the higher-order accumulator chain 130 are embodied in a deep-submicron complementary metal-oxide semiconductor integrated circuit. The six bit accumulators of both the lower-order accumulator chain 120 and the higher-order accumulator chain 130 are conventional accumulators well known by one skilled in the art.

Associated with the higher-order accumulator chain 130 is the pre-accumulator delay logic 160. The pre-accumulator delay logic 160 receives the high-order bits from the splitter 110 and provides a delay therefor before processing by the first accumulator of the higher-order accumulator chain 130. Also associated with the higher-order accumulator chain 130, and additionally the lower-order accumulator chain 120, is the inter-accumulator delay logic 170. The inter-accumulator delay logic 170 provides appropriate delays during processing of the high-order and the low-order bits to ensure alignment of bits. Since there is only one accumulator chain in a conventional MASH3 sigma-delta accumulator, the pre-accumulator delay logic 160 and the inter-accumulator delay logic 170 are not required to ensure proper alignment of bits during processing. The pre-accumulator delay logic 160 and the inter-accumulator delay logic 170 may include conventional digital delays typically employed to delay bits of data.

The combiner 180 is coupled to both the lower-order accumulator chain 120 and the higher-order accumulator chain 130 and is configured to align results therefrom to generate output bits of a given order. The combiner 180 may be a conventional combiner employed in common MASH3 sigma-delta modulators. The combiner 180 can provide an output in a unit-weighted format. Thus, a final arithmetic operation to obtain a digital binary or analog proportional signal can be deferred to subsequent operations performed by a digital-to-continuous domain converter coupled thereto.

Carryouts of each accumulator of the lower-order accumulator chain 120 are coupled to an accumulator of a corresponding stage of the higher-order accumulator chain 130. The carryouts of each accumulator of the higher-order accumulator chain 130 are coupled to the inter-accumulator delay logic 170 or the combiner 180. This differs from a conventional MASH3 sigma-delta modulator where all of the carryouts of the single accumulator chain are coupled to the combiner 180.

A clock signal (CLK in FIG. 1) is provided to the MASH3 sigma-delta modulator 100 for a synchronous operation. The MASH3 sigma-delta modulator 100 performs a 12 bit addition by the first accumulator of the lower-order accumulator chain 120 adding the six lower-order bits in a first clock cycle while the six higher-order bits are delayed by the pre-accumulator delay logic 160. In a next clock cycle, the first accumulator of the higher-order accumulator chain 130 adds the six higher-order bits with the carryout from the first accumulator of the lower-order accumulator chain 120. Subsequent 12 bit additions are similarly performed by the second and third stage accumulators of the lower-order accumulator chain 120 and the higher-order accumulator chain 130 with the inter-accumulator delay logic 170 providing the proper delays between clock cycles to ensure proper alignment.

A reset signal (arstz) is also provided for each stage of the MASH3 sigma-delta modulator 100. The reset signals allow stage reductions of the sigma-delta modulator 100 by powering-down stages thereof. For example, instead of a third order modulator, arstz3 may be asserted to reset the third stage of the sigma-delta modulator 100 and provide a second order modulator. For a third order modulator, arstz1, arstz2 and arstz3 will not be asserted such that each stage is not reset (unreset). Operation of the reset signals may be controlled by user input.

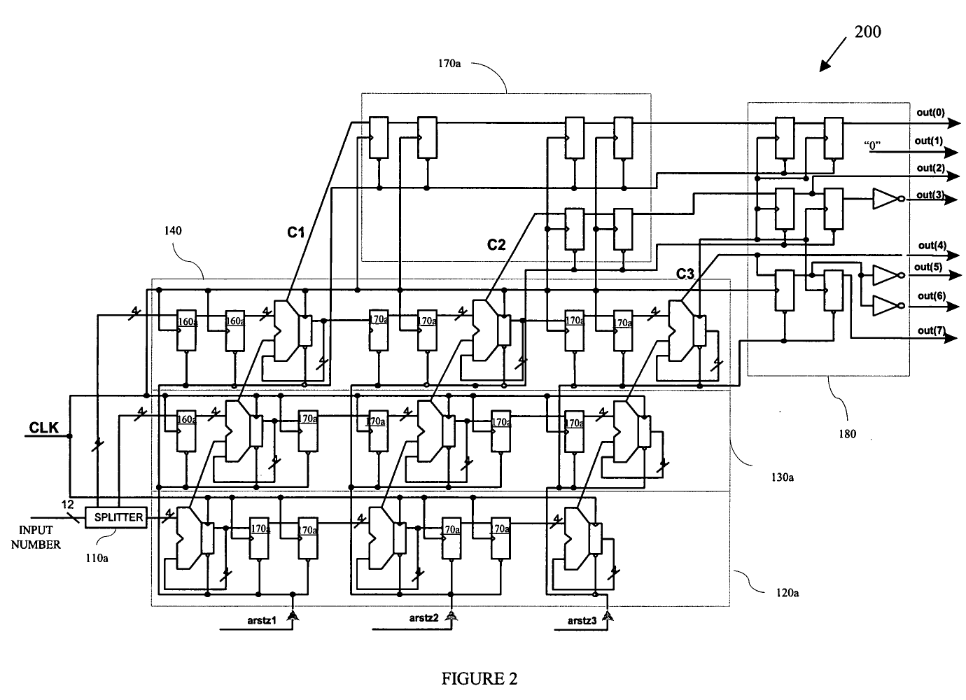

Turning now to FIG. 2, illustrated is a schematic diagram of one embodiment of a MASH3 sigma-delta modulator, generally designated 200, constructed according to the principles of the present invention in which three accumulator chains are employed to process a third of the input number bits apiece. The MASH3 sigma-delta modulator 200 includes a splitter 110a, a lower-order accumulator chain 120a, a higher-order accumulator chain 130a, a third accumulator chain 140, pre-accumulator delay logic 160a, inter-accumulator delay logic 170a and the combiner 180.

The MASH3 sigma-delta modulator 200 functions similar to the MASH3 sigma-delta modulator 100 except the input number is divided into three groups of four bits instead of two groups of six bits. Accordingly, the third accumulator chain 140 is needed for processing a third of the input number bits. As illustrated, the third accumulator chain 140 processes the four bits that are most significant bits. Additionally, the components of FIG. 2 denoted with an “a” function as corresponding components in FIG. 1 except the “a” components of FIG. 2 process the input number in groups of four bits. Accordingly, the accumulators of the lower-order accumulator chain 120a, the higher-order accumulator chain 130a and the third accumulator chain 140 are conventional four bit accumulators instead of six bit accumulators. Furthermore, the pre-accumulator delay logic 160a and the inter-accumulator delay logic 170a also include additional delays to ensure proper alignment for processing the three groups of four bits.

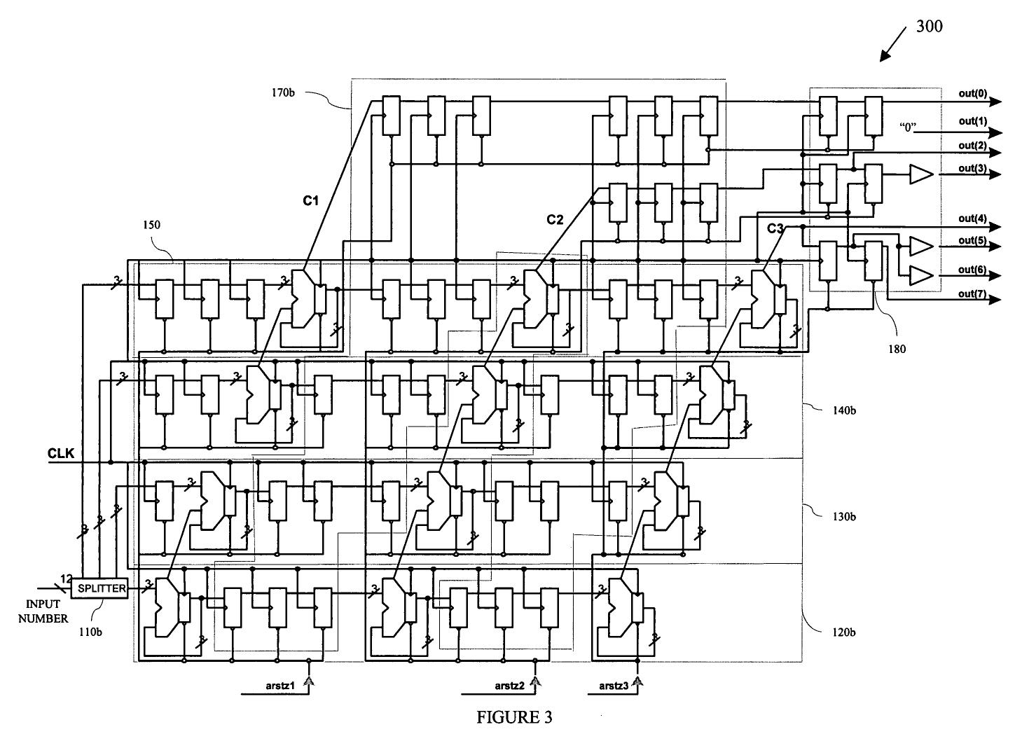

Turning now to FIG. 3, illustrated is a schematic diagram of one embodiment of a MASH3 sigma-delta modulator, generally designated 300, constructed according to the principles of the present invention in which four accumulator chains are employed to a quarter of the input number bits apiece. The MASH3 sigma-delta modulator 300 includes a splitter 110b, a lower-order accumulator chain 120b, a higher-order accumulator chain 130b, a third accumulator chain 140b, a fourth accumulator chain 150, pre-accumulator delay logic 160b, inter-accumulator delay logic 170b and the combiner 180.

The MASH3 sigma-delta modulator 300 functions similar to the MASH3 sigma-delta modulator 200 except the input number is divided into four groups of three bits instead of three groups of four bits. Accordingly, the fourth accumulator chain 150 is needed for processing a fourth of the input number bits. As illustrated, the fourth accumulator chain 150 processes the three bits that are most significant bits. Additionally, the components of FIG. 3 denoted with an “b” function as corresponding components in FIG. 2 except the “b” components of FIG. 3 process the input number in groups of three bits. Accordingly, the accumulators of the lower-order accumulator chain 120b, the higher-order accumulator chain 130b, the third accumulator chain 140b and the fourth accumulator chain 150 are conventional three bit accumulators instead of four bit accumulators. Furthermore, the pre-accumulator delay logic 160b and the inter-accumulator delay logic 170b also include additional delays to ensure proper alignment for processing the four groups of three bits.

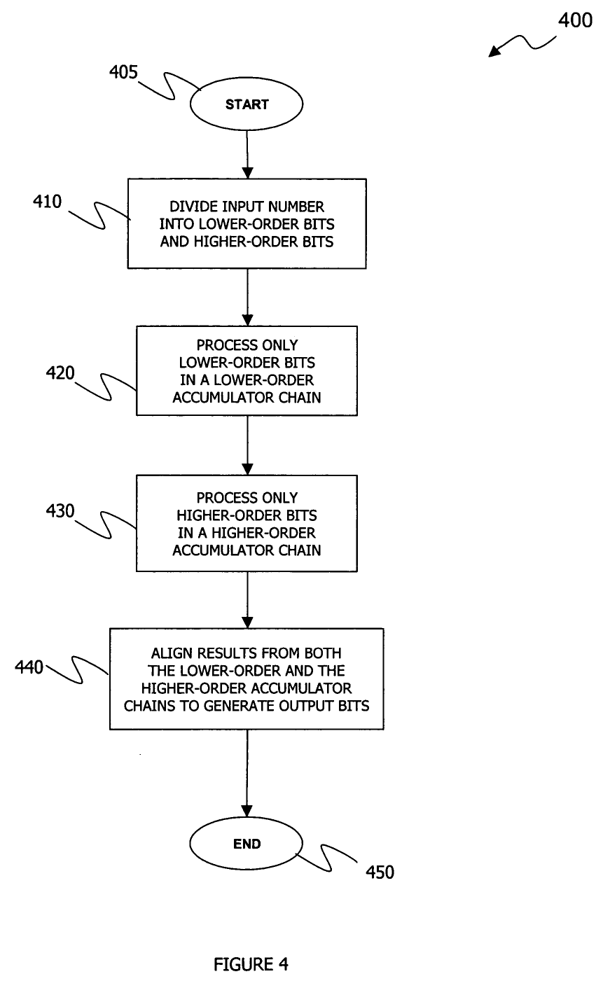

Turning now to FIG. 4, illustrated is a flow diagram of one embodiment of a method of performing a sigma-delta modulation carried out according to the principles of the present invention. The method 400 begins with an intent to perform sigma-delta modulation.

After beginning, bits of an input number are divided into lower-order bits and higher-order bits in a step 410. The number of lower-order bits may equal the number of higher-order bits. In some embodiments, the input number may be divided into multiple groups of lower-order and higher-order bits. For example, the input number may be divided into three groups of bits. Of course, one skilled in the art will understand that the input number can be divided and further processed in groups of even one bit. Dividing the bits of the input number into the lower-order and higher-order bits allows parallel processing to increase throughput and allow modulation by a deep-submicron complementary metal-oxide semiconductor integrated circuit for RF frequencies.

After dividing, only lower-order bits of an input number are processed in a lower-order accumulator chain in a step 420. In some embodiments, the number of accumulators in the lower-order accumulator chain equal in number both accumulators in a higher-order accumulator chain and a given order. For example, for third order sigma-delta modulation, the lower-order accumulator chain and the higher-order accumulator chain would have three accumulators for three stages.

After processing the lower-order bits, only higher-order bits of the input number are processed in a higher-order accumulator chain in a step 430. The higher-order accumulator chain may have pre-accumulator delay logic associated therewith to ensure proper alignment of the bits when processing. The lower-order accumulator chain and the higher-order accumulator chain may also have inter-accumulator delay logic associated therewith to ensure proper bit alignment. Depending on the number of accumulator chains, the amount of the pre-accumulator delay logic and the inter-accumulator delay logic may vary.

After processing the higher-order bits, results from both the lower-order and higher-order accumulator chains are aligned to generate output bits of a given order in a step 440. Some of the results may be aligned employing a portion of the inter-accumulator delay logic. A combiner may also be used to provide alignment for the output bits. After aligning the results, the method 400 ends in a step 450.

While the method(s) disclosed herein has (have) been described and shown with reference to particular steps performed in a particular order, it will be understood that these steps may be combined, subdivided, or reordered to form an equivalent method without departing from the teachings of the present invention. Accordingly, unless specifically indicated herein, the order and/or the grouping of the steps are not limitations of the present invention.

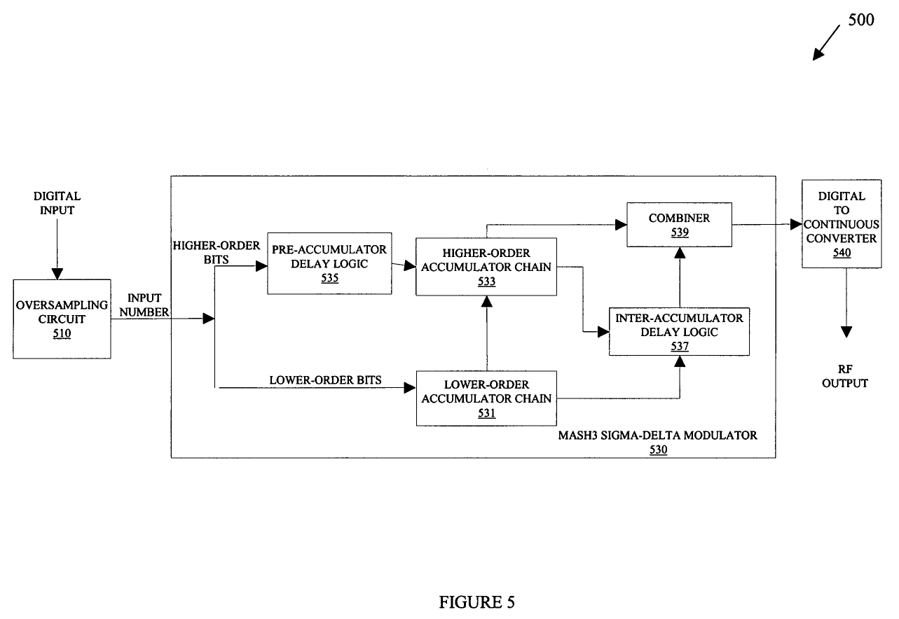

Turning now to FIG. 5, illustrated is a schematic diagram of one embodiment of a digital-to-analog converter, generally designated 500, incorporating a MASH3 sigma-delta modulator constructed according to the principles of the present invention. The digital-to-analog converter 500 includes an oversampling circuit 510, the MASH3 sigma-delta modulator 530 and a digital-to-continuous converter 540. The MASH3 sigma-delta modulator 530 includes a lower-order accumulator chain 531, a higher-order accumulator chain 533, pre-accumulator delay logic 535, inter-accumulator delay logic 537 and a combiner 539. One skilled in the art will understand that the digital-to-analog converter 500 may also included additional components typically included within a conventional digital-to-analog converter that are not illustrated or discussed.

The digital-to-analog converter 500 provides data conversion for a digital input to an analog output. The digital-to-analog converter 500 may be employed in a RF transceiver. In some embodiments, the digital-to-analog converter 500 can be built as a digital-to-RF amplitude converter if the digital-to-continuous converter 540 includes a digitally-controlled RF power amplifier.

The oversampling circuit 510, which may be an upsampler or an interpolator, is configured to provide input numbers for the MASH3 sigma-delta modulator 520 by employing a faster clock (compared to the digital input) for a zero-order hold of the digital input. The sampling rate of the oversampling circuit 510 may be at least one GHz. The oversampling circuit 510 is a conventional device that one skilled in the art will understand. The input numbers are sent to the MASH3 sigma-delta modulator 530 for noise shaping.

The MASH3 sigma-delta modulator 530 divides an input number into two groups of bits for processing. The lower-order accumulator chain 531 processes only a lower-order group of bits and the higher-order accumulator chain 533 processes only a higher-order group of bits. The number of lower-order bits and higher-order bits may be equivalent. Of course, one skilled in the art will understand the number of lower-order bits and higher-order bits may also vary. In some embodiments, the number of lower-order bits may substantially equal the number of higher-order bits. For example, a total number of bits may equal seven with either three or four bits considered higher-order bits and either four or three bits considered lower-order bits, respectively. Additionally, the number of groups of lower-order bits and higher-order bits may also vary. Thus, the MASH3 sigma-delta modulator 530 may have additional accumulator chains configured to only process a designated group of bits.

Associated with the higher-order accumulator chain 533 is the pre-accumulator delay logic 535. The pre-accumulator delay logic 535 is configured to provide a delay for the higher-order bits to ensure proper alignment with the lower-order bits during processing. Associated with both the lower-order accumulator chain 531 and the higher-order accumulator chain 533 is the inter-accumulator delay logic 537. The inter-accumulator delay logic 537 provides delays for all of the bits to provide additional alignment during processing.

Coupled to both the lower-order and higher-order accumulator chains, the combiner 539 aligns results therefrom to generate output bits of a given order. Coupled to the combiner 539, the digital-to-continuous converter 540, such as a digital-to-analog or a digital-to-amplitude converter, converts the generated output bits from a digital code to a continuous domain such as, an analog voltage or current quantity. The digital-to-continuous converter 540 may employ unit-weighted elements, such as, transistors or varactors. The digital-to-continuous converter 540, for example, may vary a current output, or an output resistance, based on the generated output bits input. Both the combiner 539 and the digital-to-continuous converter 540 are conventional devices that one skilled in the art will understand.

In summary, the present invention permits high-orders of sigma-delta modulators that process a high number of bits to be implemented at RF frequencies. Narrower accumulators in the modulators allow a fully digital approach for RF amplitude modulation in general and Enhanced Data Rate for GSM Evolution (EDGE) in particular. The present invention therefore uniquely provides parallel processing in closed-loop modulators employing narrower accumulators that can be fully digitally implemented. Background information on sigma-delta modulators, can be found in Norsworthy, et al., “Delta-Sigma Data Converters, Theory, Design and Simulation”, IEEE Press 1997, incorporated herein by reference.

Although the present invention has been described in detail, those skilled in the art should understand that they can make various changes, substitutions and alterations herein without departing from the spirit and scope of the invention in its broadest form.

1. A sigma-delta modulator, comprising:
a lower-order accumulator chain configured to process only lower-order bits of an input number;
a higher-order accumulator chain configured to process only higher-order bits of said input number; and
a combiner coupled to both said lower-order and higher-order accumulator chains and configured to align results therefrom to generate output bits of a given order.

2. The sigma-delta modulator as recited in claim 1 wherein said lower-order bits equal in number said higher-order bits.

3. The sigma-delta modulator as recited in claim 1 wherein accumulators in said lower-order accumulator chain equal in number both accumulators in said higher-order accumulator chain and said given order.

4. The sigma-delta modulator as recited in claim 1 wherein said higher-order accumulator chain has pre-accumulator delay logic associated therewith.

5. The sigma-delta modulator as recited in claim 1 wherein said lower-order accumulator chain and said higher-order accumulator chain have inter-accumulator delay logic associated therewith.

6. The sigma-delta modulator as recited in claim 1 further comprising at least one other accumulator chain.

7. The sigma-delta modulator as recited in claim 1 wherein said lower-order accumulator chain and said higher-order accumulator chain are embodied in a deep-submicron complementary metal-oxide semiconductor integrated circuit.

8. The sigma-delta modulator as recited in claim 1 wherein said lower-order accumulator chain and said higher-order accumulator chain have multiple stages and each of said multiple stages is controlled by an unique reset signal.

9. A method of performing sigma-delta modulation, comprising:
processing only lower-order bits of an input number in a lower-order accumulator chain;
processing only higher-order bits of said input number in a higher-order accumulator chain; and
aligning results from both said lower-order and higher-order accumulator chains to generate output bits of a given order.

10. The method as recited in claim 9 wherein said lower-order bits equal in number said higher-order bits.

11. The method as recited in claim 9 wherein accumulators in said lower-order accumulator chain equal in number both accumulators in said higher-order accumulator chain and said given order.

12. The method as recited in claim 9 wherein said higher-order accumulator chain has pre-accumulator delay logic associated therewith.

13. The method as recited in claim 9 wherein said lower-order accumulator chain and said higher-order accumulator chain have inter-accumulator delay logic associated therewith.

14. The method as recited in claim 9 further comprising processing other bits of said input number in at least one other accumulator chain.

15. The method as recited in claim 9 wherein said lower-order accumulator chain and said higher-order accumulator chain are embodied in a deep-submicron complementary metal-oxide semiconductor integrated circuit.

16. The method as recited in claim 9 wherein said lower-order accumulator chain and said higher-order accumulator chain have multiple stages and said method further comprises controlling each of said multiple stages by an unique reset signal.

17. An digital-to-analog converter, comprising:
digital circuitry configured to provide input numbers from a digital input;
a sigma-delta modulator coupled to said digital circuitry and including:
a lower-order accumulator chain that processes only lower-order bits of said input numbers,
a higher-order accumulator chain that processes only higher-order bits of said input numbers, and
a combiner, coupled to both said lower-order and higher-order accumulator chains, that aligns results therefrom to generate output bits of a given order; and
a digital-to-continuous converter, coupled to said sigma-delta modulator, that converts said output bits into a continuous domain.

18. The digital-to-analog converter as recited in claim 17 wherein said sigma-delta modulator is a multistage noise shaping (MASH) sigma-delta modulator.

19. The digital-to-analog converter as recited in claim 17 wherein said input digital circuitry includes an upsampler or an interpolator.

20. The digital-to-analog converter as recited in claim 17 wherein said lower-order bits equal in number said higher-order bits.

21. The digital-to-analog converter as recited in claim 17 wherein accumulators in said lower-order accumulator chain equal in number both accumulators in said higher-order accumulator chain and said given order.

22. The digital-to-analog converter as recited in claim 17 wherein said higher-order accumulator chain has pre-accumulator delay logic associated therewith.

23. The digital-to-analog converter as recited in claim 18 wherein said lower-order accumulator chain and said higher-order accumulator chain have inter-accumulator delay logic associated therewith.

24. The digital-to-analog converter as recited in claim 17 further comprising at least one other accumulator chain.

25. The digital-to-analog converter as recited in claim 17 wherein said lower-order accumulator chain and said higher-order accumulator chain are embodied in a deep-submicron complementary metal-oxide semiconductor integrated circuit.

26. The digital-to-analog converter as recited in claim 17 wherein said lower-order accumulator chain and said higher-order accumulator chain have multiple stages and each of said multiple stages is controlled by an unique reset signal.

27. The digital-to-analog converter as recited in claim 17 wherein said digital-to-continuous converter includes a digitally-controlled RF power amplifier and said digital-to-analog converter is a digital-to-RF amplitude converter.

28. The digital-to-analog converter as recited in claim 17 wherein said generated output bits are in a unit-weighted format and said digital-to-continuous converter employs a unit-weighted element for processing thereof.
